(19) United States
(12) Patent Application Publication
(10) Pub. No.: US 2023/0314950 A1
(43) Pub. Date: Oct. 5, 2023

(54) FLEXIBLE SUBSTRATE AND MANUFACTURING METHOD THEREOF

(71) Applicant: E Ink Holdings Inc., HSINCHU (TW)

(72) Inventor: Hsien-Yi HSIAO, HSINCHU (TW)

(21) Appl. No.: 18/156,380

(22) Filed: Jan. 18, 2023

(30) Foreign Application Priority Data
Apr. 1, 2022 (TW) 111112735

(51) Int. Cl. G03F 7/16; G03F 7/20; G03F 7/085; G03F 7/11

(52) U.S. Cl. CPC G03F 7/168; G03F 7/085; G03F 7/11; G03F 7/7065

(57) ABSTRACT

A flexible substrate includes a plastic film and an overcoat layer. The plastic film includes a main portion and plural fillers. The fillers are located in the main portion or on a surface of the main portion. The overcoat layer covers the plastic film and is in contact with the plastic film. A material of the overcoat layer includes polyimide (PI), polybenzoxazole (PBO), benzocyclobutene (BCB), acrylic resin, epoxy resin, siloxane polymer, or novolak resin.

### RELATED APPLICATIONS

This application claims priority to Taiwan Application Serial Number 111112735, filed Apr. 01, 2022, which is herein incorporated by reference.

### BACKGROUND

### Field of Invention

The present disclosure relates to a flexible substrate and a manufacturing method of the flexible substrate.

### Description of Related Art

In today’s market full of a wide variety of consumer electronic products, reflective display devices, e.g. electronic papers, now have extensively utilized as display screens. A display medium layer of a reflective display device is formed of the main elements of microcapsules that have white and black charged particles. The white and black charged particles are driven to move by applying a voltage to the display medium layer, such that each pixel displays a black color, a white color or a gray level. Since the reflective display device utilizes an incident light that irradiates the display medium layer to achieve the purpose of display, the reflective display needs no backlight to reduce power consumption.

In order to make the reflective display device have bendable feature, a thin film transistor array is usually formed on a soft plastic film. However, fillers in the soft plastic film would induce black point defects, and the black point defects appear more obvious with the higher the process temperature. The fillers and the plastic material have poor heat resistance, and thermal cracking leads to the precipitation or crystallization of low molecular weight oligomers, or leads to aggregation with the filler as the core. In addition, most plastic films are generally manufactured by roll to roll, and the process may cause uneven scratches on a surface, particle defects, gel defects, etc., and it is difficult to improve the product yield.

### SUMMARY

One aspect of the present disclosure provides a flexible substrate.

According to some embodiments of the present disclosure, a flexible substrate includes a plastic film and an overcoat layer. The plastic film includes a main portion and a plurality of fillers, wherein the fillers are located in the main portion or on a surface of the main portion. The overcoat layer covers the plastic film and is in contact with the plastic film, wherein a material of the overcoat layer includes polyimide (PI), polybenzoxazole (PBO), benzocyclobutene (BCB), acrylic resin, epoxy resin, siloxane polymer, or novolak resin.

In some embodiments, the overcoat layer includes a color resist.

In some embodiments, the color resist is tan, burgundy, red, (dark) blue, green, white or black.

In some embodiments, a thickness of the overcoat layer is in a range from 1 µm to 20 µm.

In some embodiments, a thermal expansion coefficient (CTE) of the overcoat layer is smaller than 60 ppm/°C, a thermal decomposition temperature (Td) of the overcoat layer is greater than 100° C., and a dielectric constant is smaller than 5.

In some embodiments, a Young’s modulus of the overcoat layer is greater than or equal to 1.5 Gpa, a tensile stress of the overcoat layer is greater than or equal to 100 Mpa, and a elongation of the overcoat layer is greater than or equal to 10%.

In some embodiments, the flexible substrate further includes a thin film transistor (TFT) array located on the overcoat layer.

In some embodiments, the main portion of the plastic film is a polyimide (PI) film, a polyethylene naphthalate (PEN) film, a polyethylene terephthalate (PET) film, polymethyl methacrylate (PMMA), polyether sulfone (PES), or polyarylate (PAR).

In some embodiments, a material of the fillers includes silicon nitride, silicon oxide, silicon oxynitride, or aluminium oxide.

Another aspect of the present disclosure provides a manufacturing method of a flexible substrate.

According to some embodiments of the present disclosure, a manufacturing method of a flexible substrate includes disposing a plastic film on a carrier, wherein the plastic film includes a main portion and a plurality of fillers, and the fillers are located in the main portion or on a surface of the main portion; coating an overcoat layer on the plastic film such that the overcoat layer covers the plastic film and is in contact with the plastic film, wherein a material of the overcoat layer includes polyimide (PI), polybenzoxazole (PBO), benzocyclobutene (BCB), acrylic resin, epoxy resin, siloxane polymer, or novolak resin; and removing the carrier.

In some embodiments, coating the overcoat layer on the plastic film includes spin coating or slot-die coating.

In some embodiments, disposing the plastic film on the carrier includes spraying an adhesive on one of the carrier and the plastic film.

In some embodiments, the manufacturing method of the flexible substrate further includes after disposing the plastic film on the carrier, baking the adhesive.

In some embodiments, the manufacturing method of the flexible substrate further includes after baking the adhesive and before coating the overcoat layer, detecting a defect of the plastic film.

In some embodiments, baking the adhesive is at a temperature in a range from 150° C. to 400° C. for 20 minutes to 120 minutes.

In some embodiments, the manufacturing method of the flexible substrate further includes after coating the overcoat layer on the plastic film, baking the overcoat layer.

In some embodiments, baking the overcoat layer is at a temperature in a range from 150° C. to 400° C. for 60 minutes to 120 minutes.

In some embodiments, the manufacturing method of the flexible substrate further includes after baking the overcoat layer, detecting a defect of the plastic film.

In some embodiments, the manufacturing method of the flexible substrate further includes after detecting the defect of the plastic film, forming a thin film transistor array on the overcoat layer.

In some embodiments, removing the carrier is performed after forming the thin film transistor array on the overcoat layer.

In the aforementioned embodiments of the present disclosure, since the flexible substrate includes the overcoat layer that covers the plastic film, and the material of the overcoat layer includes polyimide (PI), polybenzoxazole (PBO), benzocyclobutene (BCB), acrylic resin, epoxy resin, siloxane polymer, or novolak resin, the flexible substrate may have good thermal, physical, and mechanical properties and good chemical resistance to meet subsequent process requirements, such as a thin film transistor array process. The overcoat layer of the flexible substrate can cover black point defects caused by the fillers of the plastic film, thereby having concealer effect. Moreover, the overcoat layer can planarize uneven scratches, particle defects, gel defects, etc., on the surface of the plastic film, so as to improve the surface defects of the plastic film and increase the product yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a manufacturing method of a flexible substrate according to one embodiment of the present disclosure.

FIG. 2 is a perspective view of a plastic film after being disposed on a carrier according to one embodiment of the present disclosure.

FIGS. 3 and 4 are cross-sectional views of plastic films according to some embodiments of the present disclosure.

FIG. 5 is a perspective view of an overcoat layer after being formed on the plastic film of FIG. 2.

FIGS. 6 and 7 are cross-sectional views of the overcoat layer that planarizes the plastic films having a defect.

FIG. 8 is a cross-sectional view of the overcoat layer that planarizes the plastic film having uneven scratches.

FIG. 9 is a perspective view of a thin film transistor array after being formed on the overcoat layer of FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

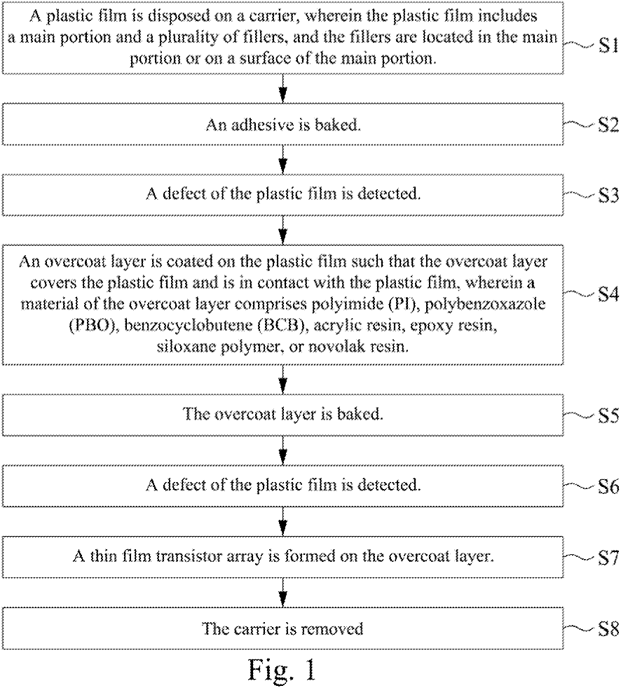

FIG. 1 is a flow chart of a manufacturing method of a flexible substrate according to one embodiment of the present disclosure. The manufacturing method of the flexible substrate includes step S1 to step S8. In step S1, a plastic film is disposed on a carrier, wherein the plastic film includes a main portion and a plurality of fillers, and the fillers are located in the main portion or on a surface of the main portion. Thereafter, in step S2, an adhesive is baked. Afterwards, in step S3, a defect of the plastic film is detected. Next, in step S4, an overcoat layer is coated on the plastic film such that the overcoat layer covers the plastic film and is in contact with the plastic film, wherein a material of the overcoat layer comprises polyimide (PI), polybenzoxazole (PBO), benzocyclobutene (BCB), acrylic resin, epoxy resin, siloxane polymer, or novolak resin. Subsequently, in step S5, the overcoat layer is baked. Thereafter, in step S6, a defect of the plastic film is detected. Thereafter, in step S7, a thin film transistor array is formed on the overcoat layer. Finally, in step S8, the carrier is removed.

The manufacturing method of the flexible substrate is not limited to the above steps S1 to S8. For example, in some embodiments, the manufacturing method can further include other steps between two of the above steps, or can further include other steps before step S1 and after step S8.

In the following description, each step of the manufacturing method of the flexible substrate will be explained.

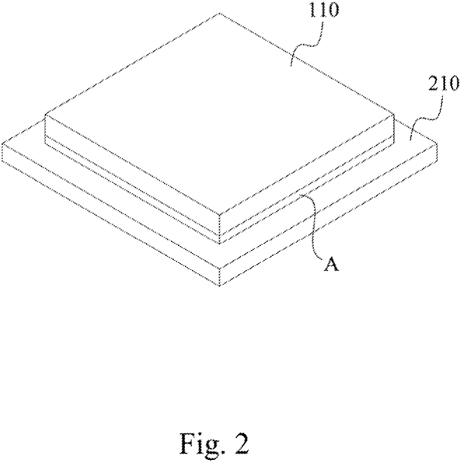

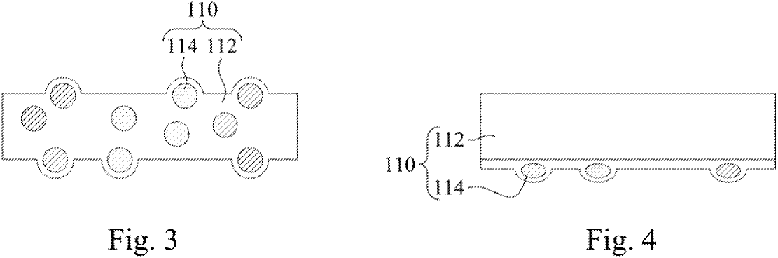

FIG. 2 is a perspective view of a plastic film 110 after being disposed on a carrier 210 according to one embodiment of the present disclosure. FIGS. 3 and 4 are cross-sectional views of the plastic films 110 according to some embodiments of the present disclosure. First of all, the plastic film 110 is disposed on the carrier 210, wherein the plastic film 110 includes a main portion 112 and a plurality of fillers 114. In some embodiments, the fillers 114 are located in the main portion 112, and may be randomly distributed in the main portion 112, as shown in FIG. 3. In some embodiments, the fillers 114 are located on the surface of the main portion 112, such as the fillers 114 coated on one side of the main portion 112, as shown in FIG. 4. The material of the carrier 210 may be, but not limited to glass. In disposing plastic film 110 on the carrier 210, an adhesive A may be sprayed on one of the carrier 210 and the plastic film 110, and then the plastic film 110 is adhered to the carrier 210 by the adhesive A, such that the adhesive A is located between the plastic film 110 and the carrier 210.

In this embodiment, the main portion 112 of the plastic film 110 may be a polyimide (PI) film, a polyethylene naphthalate (PEN) film, a polyethylene terephthalate (PET) film, polymethyl methacrylate (PMMA), polyether sulfone (PES), or polyarylate (PAR). The aforementioned materials can make the plastic film 110 have bendable property, and thus the plastic film 110 can serve as a substrate below the thin film transistor (TFT) array of a reflective display device (e.g., an electronic paper). Moreover, the material of the fillers 114 may include silicon nitride (SiNx), silicon oxide (SiOx), silicon oxynitride (SiNxOy), or aluminium oxide (AlOx), and thus the plastic film 110 can have a rough surface.

After the plastic film 110 is disposed on the carrier 210, the adhesive A may be baked. In some embodiment, baking the adhesive A is at a temperature in a range from 150° C. to 400° C. for 20 minutes to 120 minutes. Thereafter, the defect of the plastic film 110 may be detected by automated optical inspection (AOI) equipment.

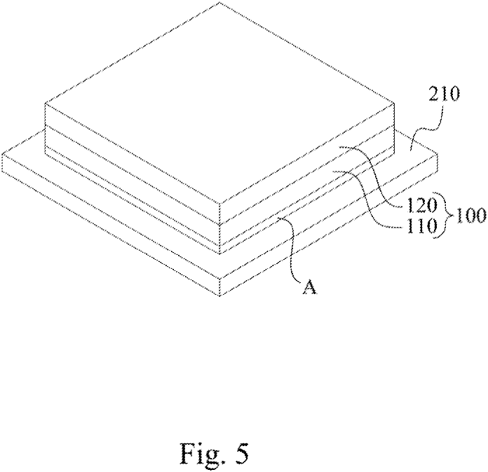

FIG. 5 is a perspective view of an overcoat layer 120 after being formed on the plastic film 110 of FIG. 2. After detecting the defect of the plastic film 110, the overcoat layer 120 is coated on the plastic film 110 such that the overcoat layer 120 covers the plastic film 110 and is in contact with the plastic film 110, wherein th material of the overcoat layer 120 may include polyimide (PI), polybenzoxazole (PBO), benzocyclobutene (BCB), acrylic resin, epoxy resin, siloxane polymer, or novolak resin. The overcoat layer 120 may be a liquid material when coating the overcoat layer 120 and before baking the overcoat layer 120, such as photosensitive resin or non-photosensitive resin. In some embodiment, coating the overcoat layer 120 on the plastic film 110 may be performed by using spin coating or slot-die coating.

After the overcoat layer 120 is coated on the plastic film 110, the overcoat layer 120 may be baked. In some embodiments, baking the overcoat layer 120 is at a temperature in a range from 150° C. to 400° C. for 60 minutes to 120 minutes. Moreover, after baking the overcoat layer 120, the defect of the plastic film 110 may be detected by automated optical inspection (AOI) equipment.

FIGS. 6 and 7 are cross-sectional views of the overcoat layer 120 that planarizes the plastic films 110 having a defect D. The defect D may be the precipitation or crystallization of low molecular weight oligomers, or may be aggregation with the filler 114 (see FIG. 3) as the core, such as a black point defect. Furthermore, the defect D may be a particle defect and a gel defect. In FIG. 6, the defect D is located in the plastic film 110. In FIG. 7, the defect D is located on the plastic film 110. The overcoat layer 120 can cover the defect D and planarize the surface of the plastic film 110, thereby having concealer effect to prevent the defect D from being detected in the subsequent process to improve the product yield.

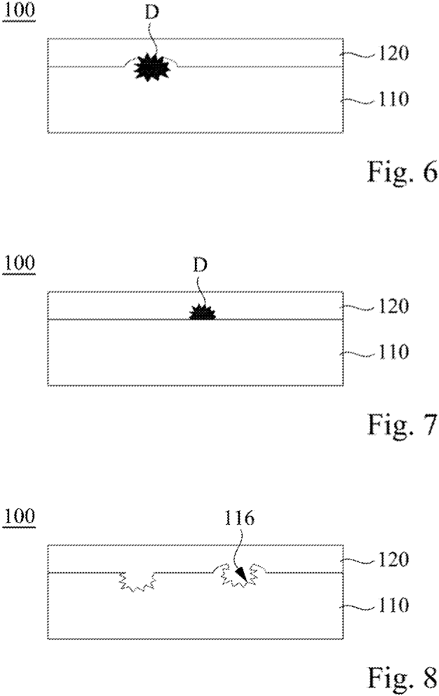

FIG. 8 is a cross-sectional view of the overcoat layer 120 that planarizes the plastic film 110 having uneven scratches 116. As shown on FIG. 8, the surface of the plastic film 110 has the uneven scratches 116. The overcoat layer 120 can cover the uneven scratches 116 and planarize the surface of the plastic film 110, which facilitates a subsquent process for manufacturing a thin film transistor array.

Specifically, since the flexible substrate 100 includes the overcoat layer 120 that covers the plastic film 110, and the material of the overcoat layer 120 includes polyimide (PI), polybenzoxazole (PBO), benzocyclobutene (BCB), acrylic resin, epoxy resin, siloxane polymer, or novolak resin, the flexible substrate 100 may have good thermal, physical, and mechanical properties and good chemical resistance to meet subsequent process requirements, such as a thin film transistor array process. The overcoat layer 120 of the flexible substrate 100 can cover black point defects caused by the fillers 114 of the plastic film 110, thereby having concealer effect. Moreover, the overcoat layer 120 can planarize uneven scratches, particle defects, gel defects, etc., on the surface of the plastic film 110, so as to improve the surface defects of the plastic film 110 and increase the product yield.

In some embodiments, the thickness of the overcoat layer 120 is in a range from 1 µm to 20 µm. The thermal expansion coefficient (CTE) of the overcoat layer 120 is smaller than 60 ppm/°C. The thermal decomposition temperature (Td) of the overcoat layer 120 is greater than 100° C. (at 1% weight loss). The dielectric constant of the overcoat layer 120 is smaller than 5 (at 1 Mhz). The Young’s modulus of the overcoat layer 120 is greater than or equal to 1.5 Gpa. The tensile stress of the overcoat layer 120 is greater than or equal to 100 Mpa. The elongation of the overcoat layer 120 is greater than or equal to 10%. As a result of such a configuration, the overcoat layer 120 may have good thermal, physical, and mechanical properties and good chemical resistance.

In addition, the overcoat layer 120 includes a color resist (pigment), and the color resist may be (dark) tan or burgundy to darken the color of the overcoat layer 120, thereby improving the concealer effect of the overcoat layer 120. In some embodiments, the color resist may be also red, (dark) blue, green, white or black, as deemed necessary by designers, and the present disclosure is not limited to this regard. As a result, the overcoat layer 120 may reduce a light transmittance for a light source of a detector (e.g., AOI), thereby preventing the defect and the scratches of the plastic film 110.

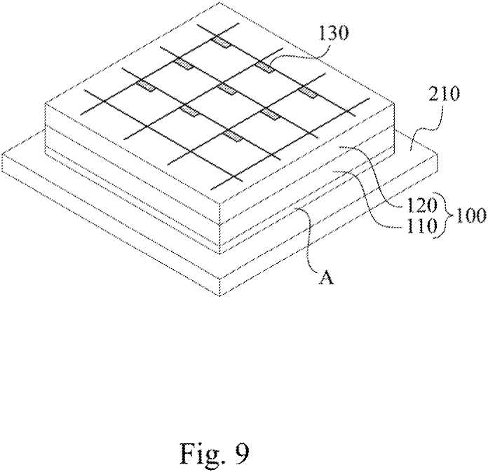

FIG. 9 is a perspective view of a thin film transistor array 130 after being formed on the overcoat layer 120 of FIG. 5. After baking the overcoat layer 120 and detecting the defect of the plastic film 110, the thin film transistor array 130 may be formed on the overcoat layer 120. Since the flexible substrate 100 has been planarized by the overcoat layer 120, the yield of the thin film transistor array 130 can be improved. Through the aforementioned steps, the flexible substrate 100 having the thin film transistor array 130 may act as a TFT substrate of a reflective display device (e.g., an electronic paper).

In the following process, a front panel laminate (FPL) having a display medium layer (e.g., an electronic ink having microcapsules) may be bonded to the flexible substrate 100. Thereafter, the carrier 210 may be removed. In other words, the carrier 210 is removed after forming the thin film transistor array 130 on the overcoat layer 120 and bonding the front panel laminate. The carrier 210 is configured to provide the support force for the flexible substrate 100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flexible substrate, comprising:
a plastic film comprising a main portion and a plurality of fillers, wherein the fillers are located in the main portion or on a surface of the main portion; and
an overcoat layer covering the plastic film and in contact with the plastic film, wherein a material of the overcoat layer comprises polyimide (PI), polybenzoxazole (PBO), benzocyclobutene (BCB), acrylic resin, epoxy resin, siloxane polymer, or novolak resin.

2. The flexible substrate of claim 1, wherein the overcoat layer comprises a color resist.

3. The flexible substrate of claim 2, wherein the color resist is tan, burgundy, red, (dark) blue, green, white or black.

4. The flexible substrate of claim 1, wherein a thickness of the overcoat layer is in a range from 1 µm to 20 µm.

5. The flexible substrate of claim 1, wherein a thermal expansion coefficient (CTE) of the overcoat layer is smaller than 60 ppm/°C, a thermal decomposition temperature (Td) of the overcoat layer is greater than 100° C., and a dielectric constant is smaller than 5.

6. The flexible substrate of claim 1, wherein a Young’s modulus of the overcoat layer is greater than or equal to 1.5 Gpa, a tensile stress of the overcoat layer is greater than or equal to 100 Mpa, and a elongation of the overcoat layer is greater than or equal to 10%.

7. The flexible substrate of claim 1, further comprising:
a thin film transistor (TFT) array located on the overcoat layer.

8. The flexible substrate of claim 1, wherein the main portion of the plastic film is a polyimide (PI) film, a polyethylene naphthalate (PEN) film, a polyethylene terephthalate (PET) film, polymethyl methacrylate (PMMA), polyether sulfone (PES), or polyarylate (PAR).

9. The flexible substrate of claim 1, wherein a material of the fillers comprises silicon nitride, silicon oxide, silicon oxynitride, or aluminium oxide.

10. A manufacturing method of a flexible substrate, comprising:
disposing a plastic film on a carrier, wherein the plastic film comprises a main portion and a plurality of fillers, and the fillers are located in the main portion or on a surface of the main portion;
coating an overcoat layer on the plastic film such that the overcoat layer covers the plastic film and is in contact with the plastic film, wherein a material of the overcoat layer comprises polyimide (PI), polybenzoxazole (PBO), benzocyclobutene (BCB), acrylic resin, epoxy resin, siloxane polymer, or novolak resin; and
removing the carrier.

11. The manufacturing method of the flexible substrate of claim 10, wherein coating the overcoat layer on the plastic film comprises spin coating or slot-die coating.

12. The manufacturing method of the flexible substrate of claim 10, wherein disposing the plastic film on the carrier comprises:
spraying an adhesive on one of the carrier and the plastic film.

13. The manufacturing method of the flexible substrate of claim 12, further comprising:
after disposing the plastic film on the carrier, baking the adhesive.

14. The manufacturing method of the flexible substrate of claim 13, further comprising:
after baking the adhesive and before coating the overcoat layer, detecting a defect of the plastic film.

15. The manufacturing method of the flexible substrate of claim 13, wherein baking the adhesive is at a temperature in a range from 150° C. to 400° C. for 20 minutes to 120 minutes.

16. The manufacturing method of the flexible substrate of claim 12, further comprising:
after coating the overcoat layer on the plastic film, baking the overcoat layer.

17. The manufacturing method of the flexible substrate of claim 16, wherein baking the overcoat layer is at a temperature in a range from 150° C. to 400° C. for 60 minutes to 120 minutes.

18. The manufacturing method of the flexible substrate of claim 16, further comprising:
after baking the overcoat layer, detecting a defect of the plastic film.

19. The manufacturing method of the flexible substrate of claim 18, further comprising:
after detecting the defect of the plastic film, forming a thin film transistor array on the overcoat layer.

20. The manufacturing method of the flexible substrate of claim 19, wherein removing the carrier is performed after forming the thin film transistor array on the overcoat layer.
